(19) United States
(12) Patent Application Publication
(10) Pub. No.: US 2026/0252149 A1
(43) Pub. Date: Aug. 27, 2026

(54) HINGE MECHANISM AND ELECTRONIC DEVICE

(71) Applicant: VIVO MOBILE COMMUNICATION CO., LTD., Dongguan (CN)

(72) Inventors: Yufeng TAN, Dongguan (CN); Xiaofei FAN, Dongguan (CN); Wenjun LIU, Dongguan (CN); Guofeng GAO, Dongguan (CN)

(73) Assignee: VIVO MOBILE COMMUNICATION CO., LTD., Dongguan (CN)

(21) Appl. No.: 19/651,780

(22) Filed: Apr. 19, 2026

Related U.S. Application Data
(63) Continuation of application No. PCT/CN2024/128781, filed on Oct. 31, 2024.

(30) Foreign Application Priority Data
Nov. 6, 2023 (CN) 202311471730.5

(51) Int. Cl. G06F 1/16

(52) U.S. Cl. CPC G06F 1/1681; G06F 1/1652

(57) ABSTRACT

A hinge mechanism includes a base, first, third, and fourth swing arms, a first support, first and second synchronous fitting members, an elastic member, and a cam member. The base is rotatably connected to the first swing arm. The first swing arm and the first support slide relative to each other. The third swing arm includes first and second arm bodies that are in sliding fit with the first support. The first and second synchronous fitting members are in linkage connection and are both movably mounted on the base. The first and second arm bodies are in transmission fit with the first synchronous fitting member. The fourth swing arm is in transmission fit with the second synchronous fitting member. The cam member and the base are relatively fastened. Two opposite ends of the elastic member respectively abut against the cam member and the base.

### CROSS-REFERENCE TO RELATED APPLICATIONS

This application is a continuation of International Application No. PCT/CN2024/128781, filed October 31, 2024, which claims priority to Chinese Patent Application No. 202311471730.5, filed November 6, 2023. The entire contents of each of the above-referenced applications are expressly incorporated herein by reference.

### TECHNICAL FIELD

This application pertains to the field of electronic device technologies, and specifically, relates to a hinge mechanism and an electronic device.

### BACKGROUND

Due to both a relatively large display area and a relatively strong portability, foldable mobile phones are increasingly popular with users. A hinge mechanism is a component for providing folding and unfolding capabilities in a foldable mobile phone, supports are usually disposed on two opposite sides of a base of the hinge mechanism, and the supports on the two sides each are connected to the base through at least one hinge arm, so that the supports on the two opposite sides of the base have a relative rotation capability. In this way, the hinge mechanism has a folding capability. In a current technology, two opposite ends of the hinge arm are usually rotatably connected to the support and the base respectively. A shaft-hole structure is usually used between the hinge arm and the support to form a rotational connection relationship. To make an electronic device in a folded state have a relatively small thickness, for a rotational relationship between the hinge arm and the base, an arc-shaped bearing bush and an arc-shaped sliding groove are usually used for mutual connection, instead of using a conventional shaft-hole rotation structure.

In a case that the hinge mechanism uses the foregoing structure, to reduce a crease generated when a display on the electronic device is folded, a manner in which a rotation angle of the hinge arm is greater than a rotation angle of the support is usually used, so that a cross section of a folded part of the display forms a structure similar to a "water drop". For example, if a maximum angle of the support relative to the base is 90°, a structural parameter of the bearing bush of the hinge arm may be designed, so that in a process in which the support rotates relative to the base, the hinge arm can rotate in a same direction relative to the support with an end of the hinge arm connected to the support as an axis. To be specific, when the support rotates relative to the base by 90°, an angle by which the hinge arm can rotate relative to the base exceeds 90°. However, because the rotation angle of the hinge arm is relatively large, a relatively large part of the bearing bush slides out of the sliding groove, thereby causing a relatively small overlap between the bearing bush and the sliding groove in the hinge mechanism in a folded state, which leads to great adverse impact on reliability of a connection relationship between the hinge arm and the base, resulting in relatively low reliability of the hinge mechanism.

### SUMMARY

According to a first aspect, an embodiment of this application provides a hinge mechanism, which includes a base, a first swing arm, a first support, a third swing arm, a fourth swing arm, a first synchronous fitting member, a second synchronous fitting member, an elastic member, and a cam member, where

the base is provided with an arc-shaped first sliding groove, a first end of the first swing arm is provided with an arc-shaped first sliding block, and the first sliding block is rotatably connected to the first sliding groove; and one of a second end of the first swing arm and the first support is provided with a second sliding block, the other is provided with a second sliding groove, and the second sliding block and the second sliding groove slide relative to each other in a thickness direction of the first support in a process in which the first support rotates relative to the base;

both the third swing arm and the first swing arm are disposed on a same side of the base, the third swing arm includes a first arm body and a second arm body, and the first arm body and the second arm body are disposed at an interval in a rotational axial direction of the first swing arm; and both the first arm body and the second arm body are rotatably connected to the base, and both the first arm body and the second arm body are in sliding fit with the first support in a direction perpendicular to the rotational axial direction;

the first synchronous fitting member and the second synchronous fitting member are in linkage connection and both are movably mounted on the base, both the first arm body and the second arm body are in transmission fit with the first synchronous fitting member, and the fourth swing arm is in transmission fit with the second synchronous fitting member, so that the third swing arm and the fourth swing arm are reversely rotatable relative to the base; and

the cam member is slidably mounted on the base in the rotational axial direction, the cam member is relatively fastened to the base in a direction around the rotational axial direction, the cam member is disposed on an end face at an end of the second arm body away from the first arm body, the second arm body is in cam fit with the cam member, and in the rotational axial direction, one end of the elastic member abuts against a side of the cam member away from a cam surface of the cam member, and the other end of the elastic member is relatively fastened to the base.

According to a second aspect, an embodiment of this application discloses an electronic device, which includes the foregoing hinge mechanism.

The embodiments of this application disclose the hinge mechanism. The third swing arm and the fourth swing arm are respectively disposed on two opposite sides of the base of the hinge mechanism, and are both in rotating fit with the base, so that the hinge mechanism can switch between an unfolded state and a folded state. In addition, the first swing arm is disposed on a side of the base on which the third swing arm is located, and the first swing arm is in sliding fit with an arc-shaped first sliding groove on the base through an arc-shaped first sliding block of the first swing arm, so that the first swing arm can form a rotating fit relationship with the base. In addition, one of the first support and the first swing arm is provided with a second sliding groove, and the other is provided with a second sliding block. The second sliding block is configured to slide in the second sliding groove in a straight-line direction, and the second sliding groove has a component that extends in the thickness direction of the first support, so that an end of the first swing arm connected to the first support has a capability of moving relative to the first support. Therefore, a parameter such as the first sliding block of the first swing arm is designed, so that the second sliding block can slide in the second sliding groove in a process in which the first support rotates relative to the base in the first direction. In this way, when the first swing arm rotates relative to the base in the first direction, the entire first swing arm can further rotate relative to the first support in the second direction opposite to the first direction. Therefore, in a case that a parameter such as a rotation angle between the first support and the base does not change, a rotation angle between the first swing arm and the base is relatively reduced, to reduce a size of a part of the first sliding block extending out of the first sliding groove. That is, when the hinge mechanism disclosed in this embodiment of this application is in a folded state, an overlap between the first sliding block and the first sliding groove is still relatively large. This can improve fit stability between the first sliding block and the first sliding groove, and further improve reliability of the hinge mechanism.

In addition, to improve an anti-torsion capability of the hinge mechanism, in this embodiment of this application, the third swing arm includes the first arm body and the second arm body that are disposed at an interval in the rotational axial direction, to ensure that the third swing arm with a relatively small overall size can have a relatively large span in the rotational axial direction. Correspondingly, the first arm body and the second arm body are both in rotating fit with the base, and are both in sliding fit with the first support in a direction perpendicular to the rotational axial direction, to ensure that actions of the first arm body and the second arm body are consistent.

In addition, the third swing arm and the fourth swing arm can form a transmission fit relationship through the first synchronous fitting member and the second synchronous fitting member that are in linkage connection, so that the third swing arm and the fourth swing arm can synchronously generate rotation actions in opposite directions relative to the base. In this way, the hinge mechanism has a synchronous rotation capability.

In addition, the third swing arm is provided with the elastic member and the cam member, so that the third swing arm has a capability of hovering relative to the base, thereby extending an application scenario of the electronic device that uses the hinge mechanism. The elastic member abuts against a side of the second arm body of the third swing arm away from the first arm body through the cam member, so that the elastic member can always squeeze the second arm body through the cam member in a manner in which the elastic member has a preset elastic force. In this way, the second arm body and the base basically do not generate relative motion in the rotational axial direction, thereby improving action stability of the second arm body, and further improving structural accuracy and reliability of the entire hinge mechanism.

### BRIEF DESCRIPTION OF DRAWINGS

FIG. 1 is a schematic structural diagram of a hinge mechanism in an unfolded state according to an embodiment of this application;

FIG. 2 is a schematic structural diagram of a hinge mechanism in an unfolded state and in another direction according to an embodiment of this application;

FIG. 3 is a schematic structural diagram of a hinge mechanism in a folded state according to an embodiment of this application;

FIG. 4 to FIG. 6 are schematic exploded views of a hinge mechanism according to an embodiment of this application;

FIG. 7 is a schematic diagram of a partial structure including a first synchronous fitting member in a hinge mechanism according to an embodiment of this application;

FIG. 8 is a schematic structural diagram of a first swing arm in a hinge mechanism according to an embodiment of this application;

FIG. 9 is a schematic cross-sectional view of a hinge mechanism in a folded state according to an embodiment of this application;

FIG. 10 is a schematic cross-sectional view of a hinge mechanism in an unfolded state according to an embodiment of this application;

FIG. 11 is a schematic diagram of a principle of relative motion between a first support and a first swing arm in a hinge mechanism according to an embodiment of this application;

FIG. 12 is a schematic structural diagram of a hinge mechanism in a folded state according to an embodiment of this application;

FIG. 13 is a schematic structural diagram of a hinge mechanism in an unfolded state according to an embodiment of this application; and

FIG. 14 is another schematic cross-sectional view of a hinge mechanism in an unfolded state according to an embodiment of this application.

### DETAILED DESCRIPTION

The following clearly describes technical solutions in embodiments of this application with reference to accompanying drawings in the embodiments of this application. Clearly, the described embodiments are merely some rather than all of the embodiments of this application. All other embodiments obtained by a person of ordinary skill in the art based on the embodiments of this application shall fall within the protection scope of this application.

It should be noted that the terms "first", "second", and the like in the specification and claims of this application are intended to distinguish between similar objects but do not necessarily indicate a specific order or sequence. It should be understood that data used in this way is interchangeable under appropriate circumstances, so that the embodiments of this application can be implemented in an order other than that illustrated or described herein. Moreover, the terms such as "first", "second", and the like typically distinguish between objects of one category rather than limiting a quantity of objects. For example, there may be one or more first objects. In addition, in the specification and claims, "and/or" represents at least one of the connected objects, and the character "/" usually represents an "or" relationship between associated objects.

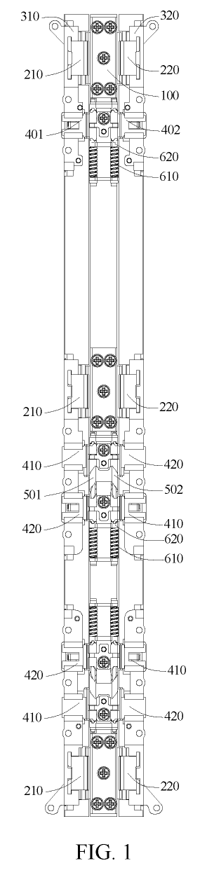

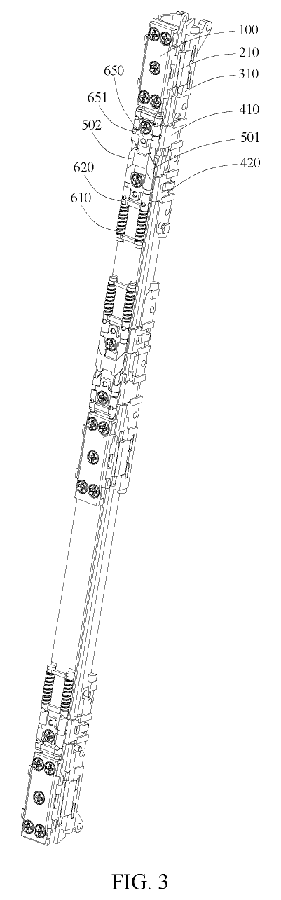

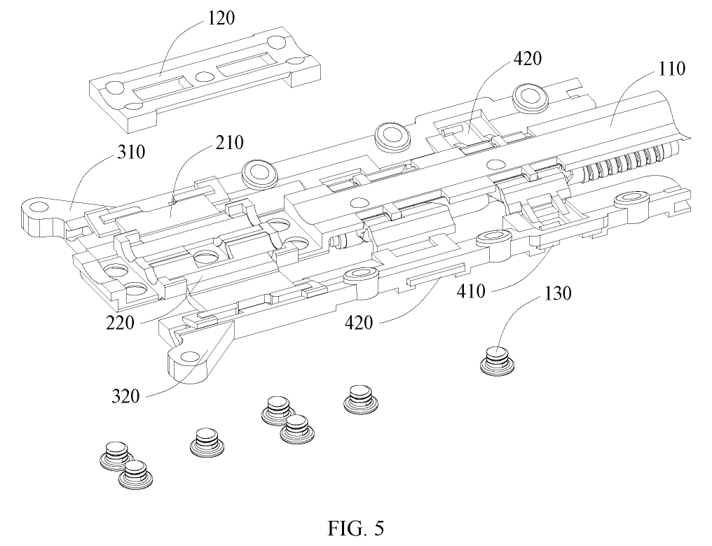

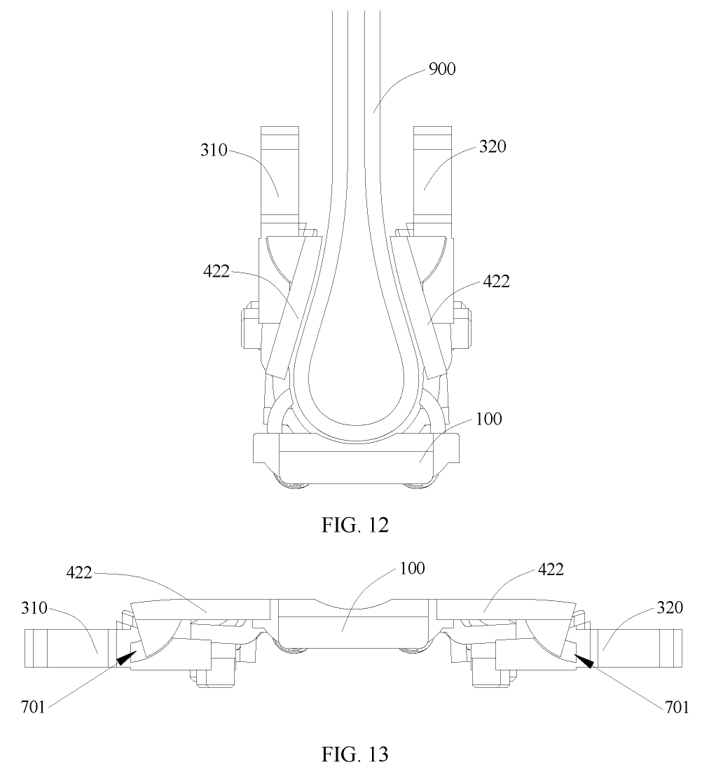

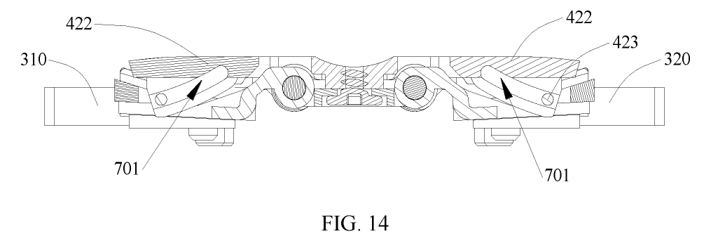

As shown in FIG. 1 to FIG. 14, embodiments of this application disclose a hinge mechanism, which may be used in an electronic device, so that the electronic device has folding and unfolding capabilities, and further has a relatively large display area and a relatively strong portability. The hinge mechanism includes a base 100, a first swing arm 210, a first support 310, a third swing arm 401, a fourth swing arm 402, a first synchronous fitting member 501, a second synchronous fitting member 502, an elastic member 610, and a cam member 620.In some embodiments, the hinge mechanism usually further includes a second swing arm 220 and a second support 320. The second swing arm 220 and the first swing arm 210 are respectively disposed on two opposite sides of the base 100, and the first swing arm 210 is configured to rotatably connect the base 100 and the first support 310. Correspondingly, the second swing arm 220 is configured to rotatably connect the base 100 and the second support 320.

As shown in FIG. 1, the first support 310 and the second support 320 are respectively disposed on two opposite sides of the base 100, so that the hinge mechanism can be connected to a first housing and a second housing (neither shown in the figure) of the electronic device through the first support 310 and the second support 320 respectively. In addition, when the first housing and/or the second housing of the electronic device are/is subject to a force, the acting force can be transferred to the first support 310 and the second support 320, so that the first support 310 and the second support 320 can rotate relative to the base 100 through the first swing arm 210 and the second swing arm 220 respectively. In this way, the entire hinge mechanism generates folding and unfolding actions, so that the electronic device using the hinge mechanism can switch between a folded state and an unfolded state. In detail, through a connector such as a screw, the first support 310 can be fixedly mounted on the first housing of the electronic device, and the second support 320 can be fixedly mounted on the second housing of the electronic device.

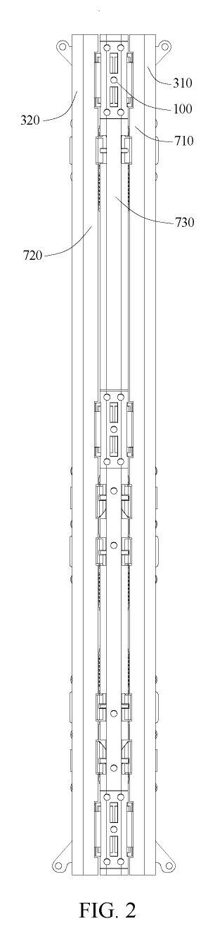

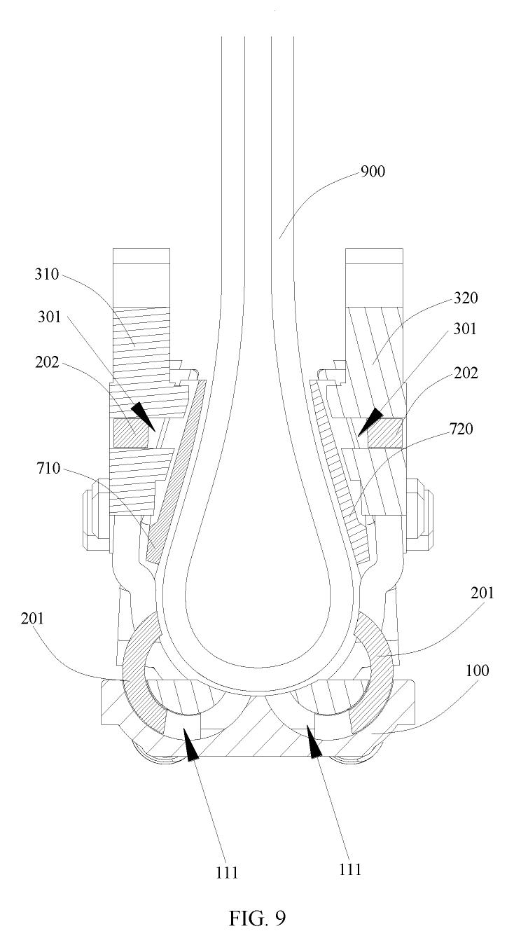

The hinge mechanism may further include other components, such as a first door plate 710 and a second door plate 720. As shown in FIG. 2, the first door plate 710 and the second door plate 720 are respectively disposed on two opposite sides of the base 100, and ends of the first door plate 710 and the second door plate 720 away from the base 100 may be correspondingly rotatably connected to the first support 310 and the second support 320 respectively. Therefore, when the hinge mechanism is in a folded state, as shown in FIG. 9, the first door plate 710 and the second door plate 720 can form a structure in a shape of a flared opening, and the flared opening faces a direction in which the base 100 is located, to provide relatively large accommodating space for a bent part in the middle of a flexible display 900, thereby preventing the flexible display 900 from being squeezed and damaged, and improving a service life of the flexible display 900.

Correspondingly, in a case that the hinge mechanism is in an unfolded state, other components in the hinge may be used to provide a support function for the first door plate 710 and the second door plate 720, so that support surfaces of the first door plate 710 and the second door plate 720 are coplanar, and a support function is provided for the flexible display 900, thereby improving a display effect and a service life of the flexible display 900. When the hinge mechanism is in the unfolded state, the components used to support the first door plate 710 and the second door plate 720 may be the third swing arm 401 and the fourth swing arm 402 or the like.

Similar to the first swing arm 210 and the second swing arm 220, the third swing arm 401 and the fourth swing arm 402 are also rotatably connected to two opposite sides of the base 100 respectively. When the hinge mechanism is used in the electronic device, the third swing arm 401 and the fourth swing arm 402 are also directly or indirectly connected to the first housing and the second housing respectively, and a synchronously relative rotation relationship may be formed between the third swing arm 401 and the fourth swing arm 402 through a structure such as a gear, so that the first housing and the second housing have a capability of synchronously rotating relative to the base 100.

In some embodiments, the third swing arm 401 and the fourth swing arm 402 each may be rotatably mounted on the base 100 through a structure such as a pin shaft, or a synchronous shaft 630 mentioned below may be reused, so that when the synchronous shaft 630 provides a mounting function for components such as the elastic member 610, each of the third swing arm 401 and the fourth swing arm 402 may form a rotational connection relationship with the base 100 through a synchronous shaft 630. In addition, as shown in FIG. 14, the third swing arm 401 and the fourth swing arm 402 each may include a sliding rod 423, the first door plate 710 and the second door plate 720 each are provided with a corresponding track groove 701, the sliding rod 423 is slidably mounted in the track groove 701, and a specific extension track of the track groove 701 and rotation tracks of the third swing arm 401 and the fourth swing arm 402 relative to the base 100 are designed, to ensure that in a process in which the third swing arm 401 and the fourth swing arm 402 rotate relative to the base 100, the first door plate 710 and the second door plate 720 can be driven to rotate relative to the base 100, so that the first door plate 710 and the second door plate 720 can switch between a mutually parallel state (corresponding to the hinge mechanism in the unfolded state) and a "flared opening state" (corresponding to the hinge mechanism in the folded state).

To enable the first support 310 to be in rotating fit with the base 100 through the first swing arm 210, and enable the second support 320 to be in rotating fit with the base 100 through the second swing arm 220, in a process of arranging the first swing arm 210 and the second swing arm 220, the first swing arm 210 and the second swing arm 220 need to be respectively disposed on two opposite sides of the base 100. A part of each of the first swing arm 210 and the second swing arm 220 needs to be connected to the base 100, and a part of each of the first swing arm 210 and the second swing arm 220 is located outside the base 100.

In detail, to ensure a relatively small thickness dimension of screen accommodating space that is formed by the hinge mechanism in the folded state and used to accommodate the display, in other words, to ensure a smaller spacing between the first support 310 and the second support 320 in the hinge mechanism in the folded state, in a process of designing a structure of the base 100, a plurality of arc-shaped first sliding grooves 111 may be disposed on the base 100, and the first swing arm 210 and the second swing arm 220 each may include an arc-shaped first sliding block 201.

In some embodiments, an end portion at a first end of each of the first swing arm 210 and the second swing arm 220 may be provided with an arc-shaped first sliding block 201, so that both the first swing arm 210 and the second swing arm 220 may respectively fit with different first sliding grooves 111 on the base 100 through respective first sliding blocks 201. In addition, rotation axes of the first swing arm 210 and the second swing arm 220 relative to the base 100 are located outside the base 100, so that a spacing between the first support 310 and the second support 320 in the hinge mechanism in the folded state may be relatively small, thereby reducing a thickness of the electronic device using the hinge mechanism in the folded state.

To reduce processing difficulty of components in the hinge mechanism, sizes of the respective first sliding blocks 201 of the first swing arm 210 and the second swing arm 220 may be correspondingly the same. In addition, in a process in which the first sliding grooves 111 are arranged on the base 100, the first sliding grooves 111 on the base 100 that are respectively configured to be corresponding to the first swing arm 210 and the second swing arm 220 may be flush with each other in a direction of a rotation axis of the first swing arm 210. This can improve action consistency between the first swing arm 210 and the second swing arm 220. In another embodiment of this application, the first sliding grooves 111 on the base 100 that are respectively configured to be corresponding to the first swing arm 210 and the second swing arm 220 may be disposed in a staggered manner in the axial direction. In a case that this technical solution is used, a width dimension of the base 100 can be reduced to some extent, so that an overall width of the hinge mechanism is relatively small. The direction of the rotation axis of the first swing arm 210 is a rotational axial direction of the first swing arm 210. The direction is parallel to a length direction of the base 100 and is perpendicular to a thickness direction of the base 100, and a width direction of the base 100 is perpendicular to both the thickness direction of the base 100 and the rotational axial direction of the first swing arm 210.

To enable the first swing arm 210 to be connected to the first support 310 and enable the first support 310 to rotate relative to the base 100, in this embodiment of this application, one of the first support 310 and the first swing arm 210 may be provided with a second sliding block 202, the other is provided with a second sliding groove 301, and the second sliding block 202 is movably mounted in the second sliding groove 301 in a straight-line direction, so that an end of the first swing arm 210 connected to the first support 310 can move relative to the first support 310, to change an overall position relationship between the first support 310 and the first swing arm 210. A sliding direction between the second sliding block 202 and the second sliding groove 301 is perpendicular to the rotational axial direction of the first swing arm 210.

In more detail, the second sliding groove 301 disposed on the first swing arm 210 or the first support 310 has a component in a thickness direction of the first support 310, which makes the end of the first swing arm 210 connected to the first support 310 have a capability of moving relative to the first support 310 in the thickness direction of the first support 310. It should be noted that, in a case that the hinge mechanism is in the unfolded state, the thickness direction of the first support 310 is parallel to the thickness direction of the base 100, in other words, the thickness direction of the first support 310 is a thickness direction of the display in an unfolded state. Correspondingly, in a case that the hinge mechanism is in the folded state, a rotation angle of the first support 310 relative to the base 100 is usually 90°, and in this state, the first support 310 and the second support 320 are parallel to each other.

In addition, in a case that the first swing arm 210 and the first support 310 of the foregoing structure are used, based on specific parameters of the first swing arm 210 and the first sliding groove 111 on the base 100, as shown in FIG. 11, parameters of the second sliding block 202 and the second sliding groove 301 are designed, to ensure that in a process in which the first support 310 rotates relative to the base 100 in a first direction and drives the first swing arm 210 to rotate relative to the base 100, the second sliding block 202 can slide relative to the second sliding groove 301, so that the end of the first swing arm 210 connected to the first support 310 can move relative to the first support 310 along the second sliding groove 301. In this case, the first swing arm 210 can rotate relative to the first support 310 in a second direction as a whole. The second direction is opposite to the first direction. For example, the first direction is a clockwise rotation direction, and the second direction is a counterclockwise rotation direction.

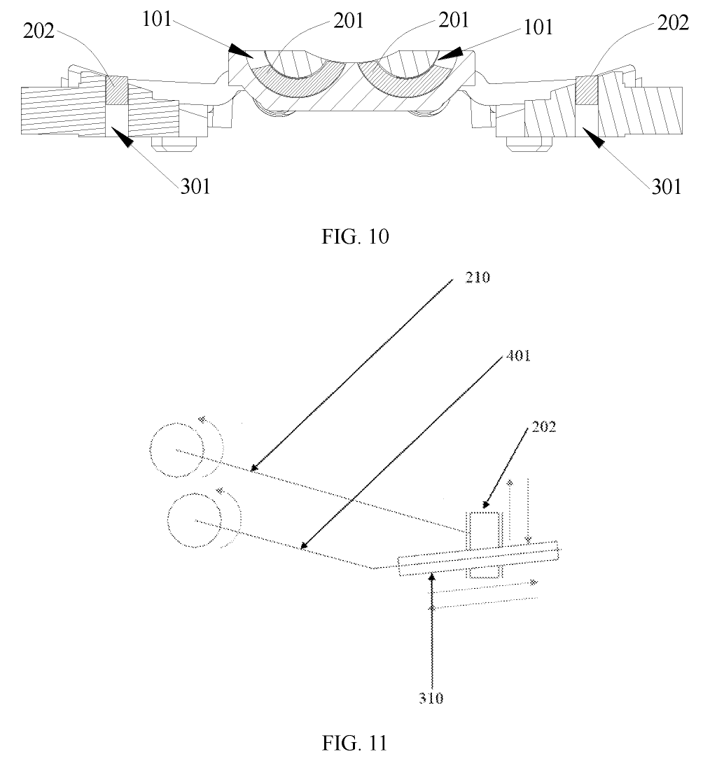

In detail, as shown in FIG. 9 and FIG. 10, in a case that the hinge mechanism is in the unfolded state, the second sliding block 202 may be located at an end of the second sliding groove 301 close to the display. In addition, in a process in which the hinge mechanism switches from the unfolded state to the folded state, the second sliding block 202 gradually slides along the second sliding groove 301 toward an end of the second sliding groove 301 away from the display, so that the second sliding block 202 is located at the end of the second sliding groove 301 away from the display in a case that the hinge mechanism is in the folded state. This can enable the first swing arm 210 to rotate relative to the first support 310 as a whole, to reduce a rotation angle of the first swing arm 210 relative to the base 100 in a case that a rotation angle of the first support 310 relative to the base 100 and a parameter of a component such as the first sliding block 201 do not change. In this way, an overlap between the first sliding block 201 and the first sliding groove 111 in the hinge mechanism in the folded state is still relatively large, thereby improving reliability of the hinge mechanism.

As described above, the hinge mechanism disclosed in this embodiment of this application includes the third swing arm 401 and the fourth swing arm 402, which are in transmission connection, so that the first housing and the second housing in the electronic device have a capability of synchronously rotating toward each other or synchronously rotating away from each other. In detail, both the third swing arm 401 and the first swing arm 210 are disposed on a same side of the base 100, and correspondingly, both the fourth swing arm 402 and the second swing arm 220 are disposed on another side of the base 100. In the hinge mechanism, to improve synchronization stability between the first housing and the second housing, dimensions of the third swing arm 401 and the fourth swing arm 402 in the rotational axial direction may be relatively large, to prevent rubbing or relative torsion of the first housing and the second housing in a relative rotation process, so as to improve reliability and user experience of the electronic device.

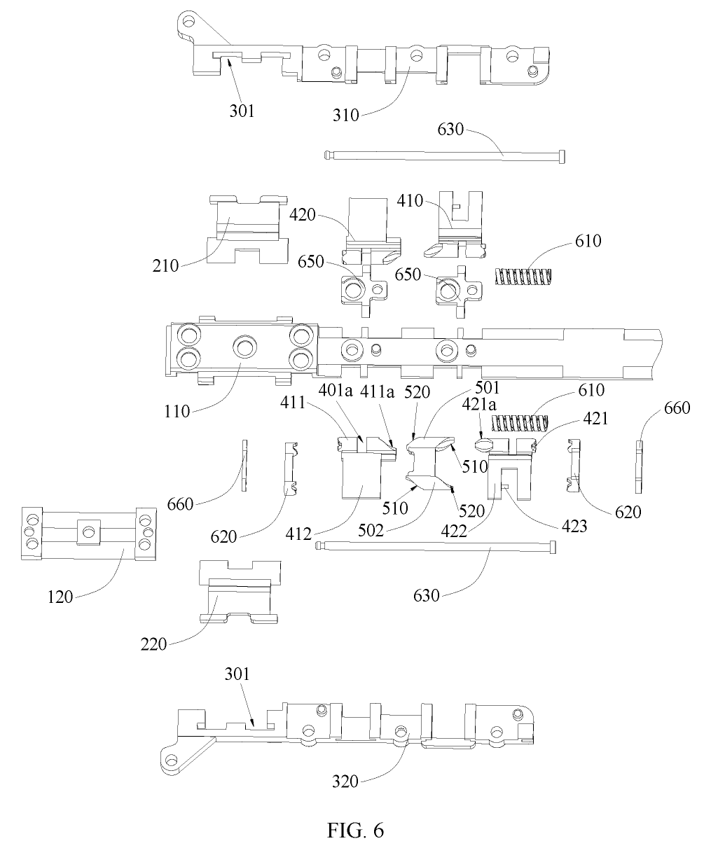

However, in a case that the foregoing technical solutions are used, space occupied by the third swing arm 401 and the fourth swing arm 402 in the hinge mechanism in the rotational axial direction is relatively large, which is not conducive to development of the hinge mechanism and the electronic device toward lightening, thinning, and miniaturization. Therefore, in this embodiment of this application, as shown in FIG. 1 and FIG. 6, the third swing arm 401 may include a first arm body 410 and a second arm body 420, and the first arm body 410 and the second arm body 420 are disposed at an interval in the rotational axial direction, to reduce a total dimension of the entire third swing arm 401 in the rotational axial direction, thereby reducing space occupied by the entire third swing arm 401 in the direction. In addition, the first arm body 410 and the second arm body 420 are spaced apart from each other in the rotational axial direction. Therefore, although an overall size of the third swing arm 401 is relatively small, because the first arm body 410 and the second arm body 420 have a relatively large span in the rotational axial direction and perform actions synchronously, it can still be ensured that the third swing arm 401 can provide a good anti-torsion function for the first support 310, so as to prevent relative torsion of the first housing and the second housing of the electronic device in a relative rotation process.

In addition, the first arm body 410 and the second arm body 420 are both rotatably connected to the base 100, and are both in sliding fit with the first support 310 in a direction perpendicular to the rotational axial direction, to ensure that actions of the first arm body 410 and the second arm body 420 are in a synchronous state, that is, movement of the second arm body 420 relative to the base 100 and the first support 310 follows movement of the first arm body 410 relative to the base 100 and the first support 310.

In some embodiments, the first arm body 410 includes a first rotating portion 411 and a first connecting portion 412 that are fixedly connected, and the second arm body 420 includes a second rotating portion 421 and a second connecting portion 422 that are fixedly connected. In addition, in both the first arm body 410 and the second arm body 420, both the first rotating portion 411 and the second rotating portion 421 are rotatably connected to the base 100, so that both the first arm body 410 and the second arm body 420 can form a rotating fit relationship with the base 100. As described above, the hinge mechanism disclosed in this embodiment of this application includes the first support 310. Both the first connecting portion 412 and the second connecting portion 422 are in sliding fit with the first support 310 in a direction perpendicular to the axial direction, and the first support 310 is fastened to the first housing of the electronic device, so that the entire third swing arm 401 can form a linkage relationship with the first housing of the electronic device, and the hinge mechanism may have higher independence, thereby facilitating processing and assembly of the hinge mechanism.

To ensure that the third swing arm 401 and the fourth swing arm 402 have a synchronization capability, as described above, the hinge mechanism disclosed in this embodiment of this application includes the first synchronous fitting member 501 and the second synchronous fitting member 502. In addition, the first synchronous fitting member 501 and the second synchronous fitting member 502 are in linkage connection, and are both movably mounted on the base 100, so that the first synchronous fitting member 501 and the second synchronous fitting member 502 can provide a synchronization function for the third swing arm 401 and the fourth swing arm 402. In some embodiments, in a case that specific structures of the first synchronous fitting member 501 and the second synchronous fitting member 502 use different solutions, there are a plurality of fit relationships between the first synchronous fitting member 501 and the second synchronous fitting member 502. For example, the first synchronous fitting member 501 and the second synchronous fitting member 502 may have a rotational connection relationship, or the first synchronous fitting member 501 and the second synchronous fitting member 502 may have a fixed connection relationship.

Correspondingly, in the case that the specific structures of the first synchronous fitting member 501 and the second synchronous fitting member 502 use different solutions, the first synchronous fitting member 501 and the second synchronous fitting member 502 may have different movable fit relationships with the base 100. For example, the first synchronous fitting member 501 and the second synchronous fitting member 502 may both have a sliding fit relationship with the base, or may both have a rotating fit relationship with the base. Regardless of structures used for the first synchronous fitting member 501 and the second synchronous fitting member 502, the first synchronous fitting member 501 and the second synchronous fitting member 502 have a same structural form, to ensure that a synchronization function can be provided for the third swing arm 401 and the fourth swing arm 402 via a linkage relationship between the first synchronous fitting member 501 and the second synchronous fitting member 502.

In some embodiments, both the first arm body 410 and the second arm body 420 of the third swing arm 401 are in transmission fit with the first synchronous fitting member 501, the fourth swing arm 402 is in transmission fit with the second synchronous fitting member 502, and the third swing arm 401 and the fourth swing arm 402 can rotate reversely relative to the base 100, so that the electronic device using the hinge mechanism can switch between an unfolded state and a folded state.

In addition, as described above, the hinge mechanism disclosed in this embodiment of this application further includes the elastic member 610 and the cam member 620, which fit with each other, so that the hinge mechanism has a hover capability, and the display of the electronic device can remain bent, thereby extending an application scenario of the electronic device. The cam member 620 is slidably mounted on the base 100 in the rotational axial direction, and the cam member 620 and the base 100 are relatively fastened in a direction around the rotational axial direction, to ensure that when the cam member 620 is squeezed by another cam surface that rotates relative to the base 100, the cam member 620 can slide in the rotational axial direction relative to the base 100, to convert a rotation action into a straight-line action, and the cam member 620 can apply a driving force to the elastic member 610.

The third swing arm 401 may be provided with the cam member 620, and in some embodiments, the cam member 620 is disposed on an end face at an end of the second arm body 420 of the third swing arm 401 away from the first arm body 410 of the third swing arm 401, so that the second arm body 420 can form a cam fit relationship with the cam member 620, and in a process in which the second arm body 420 rotates relative to the base 100, the cam member 620 can be driven to move relative to the base 100 in the rotational axial direction.

Correspondingly, in the rotational axial direction, one end of the elastic member 610 abuts against a side of the cam member 620 away from the cam surface of the cam member 620, and the other end of the elastic member 610 is relatively fastened to the base 100. Therefore, in a process in which the second arm body 420 of the third swing arm 401 rotates to squeeze the cam member 620, the cam member 620 can apply an acting force to the elastic member 610, so that the elastic member 610 stores elastic potential energy, and in a process in which the top of the cam surface of the cam member 620 fits with the top of the cam surface on the second arm body 420, the elastic member 610 can apply an elastic force to the third swing arm 401, so that the third swing arm 401 can form a relatively fastened relationship with the base 100 in the rotational axial direction without being subject to another external force. In this way, the hinge mechanism has a hover capability.

In a process of arranging the elastic member 610, a length of the elastic member 610 or an elastic status of the elastic member 610 needs to be determined based on a fit relationship between two opposite cam surfaces. In more detail, in a process in which cam surfaces on the third swing arm 401 and the cam member 620 corresponding to the third swing arm 401 move away from each other, it needs to be ensured that the elastic member 610 can be squeezed, that is, in a process in which the cam surfaces move away from each other, the elastic member 610 stores elastic potential energy, so that after the two opposite cam surfaces continue to rotate and a protrusion of one cam surface passes through a protrusion of the other cam surface, the two cam surfaces can be driven to continue to rotate relative to each other under the elastic action of the elastic member 610 until a protrusion of one cam surface is directly opposite to a recess of the other cam surface.

That is, in the hinge mechanism disclosed in the foregoing embodiment, when a protrusion of one cam surface is directly opposite to a recess of the other cam surface, if the two cam surfaces need to rotate relative to each other, an elastic force of the elastic member 610 needs to be overcome. In this way, the hinge mechanism has a damping capability, and a specific parameter of the cam surface may be controlled, so that the hinge mechanism has a hover capability at a corresponding angle. This is not limited in this specification.

In some embodiments, the elastic member 610 may be a compression spring, and the elastic member 610 may be disposed on a side of the cam member 620 corresponding to the third swing arm 401 away from the third swing arm 401, so that one end of the elastic member 610 can abut against a side of the cam member 620 away from the cam surface of the cam member 620, and the other end of the elastic member 610 is fixedly connected to the base 100 in a manner of abutment or the like, to ensure that the elastic member 610 can stably provide an elastic function. In addition, mounting difficulty of the elastic member 610 and layout difficulty of another component in the hinge mechanism can be reduced. For ease of description, in the following, the elastic member 610 is disposed by using the technical solution disclosed in this embodiment.

As described above, the elastic member 610 abuts against the end face of the cam member 620. To further improve hovering stability of the hinge mechanism, in a case that a protrusion of the cam surface of one of the cam member 620 and the third swing arm 401 faces a recess of the cam surface of the other, the elastic member 610 may still have a specific elastic force, to ensure that the elastic member 610 can always apply an elastic force to the cam member 620. In this case, the elastic member 610 can further apply an elastic force to the second arm body 420 of the third swing arm 401 through the cam member 620, so that the second arm body 420 is squeezed in the rotational axial direction. In this way, the second arm body 420 can form a relatively stable relative fastening relationship with the base 100 in the rotational axial direction, thereby eliminating a gap between the second arm body 420 and the base 100 caused when a dimension margin needs to be designed in the rotational axial direction because the second arm body 420 needs to form a rotating fit relationship with the base 100, so that assembly accuracy and action stability of the second arm body 420 are improved, and fit reliability between the entire third swing arm 401 and the base 100 and the first support 310 is higher.

The embodiments of this application disclose the hinge mechanism. The third swing arm 401 and the fourth swing arm 402 are respectively disposed on two opposite sides of the base 100 of the hinge mechanism, and are both in rotating fit with the base 100, so that the hinge mechanism can switch between an unfolded state and a folded state. In addition, the first swing arm 210 is disposed on a side of the base 100 on which the third swing arm 401 is located, and the first swing arm 210 is in sliding fit with an arc-shaped first sliding groove 111 on the base 100 through an arc-shaped first sliding block 201 of the first swing arm 210, so that the first swing arm 210 can form a rotating fit relationship with the base 100. In addition, one of the first support 310 and the first swing arm 210 is provided with a second sliding groove 301, and the other is provided with a second sliding block 202. The second sliding block 202 can slide in the second sliding groove 301 in a straight-line direction, and the second sliding groove 301 has a component that extends in the thickness direction of the first support 310, so that an end of the first swing arm 210 connected to the first support 310 has a capability of moving relative to the first support 310. Therefore, a parameter such as the first sliding block 201 of the first swing arm 210 is designed, so that the second sliding block 202 can slide in the second sliding groove 301 in a process in which the first support 310 rotates relative to the base 100 in the first direction. In this way, when the first swing arm 210 rotates relative to the base 100 in the first direction, the entire first swing arm 210 can further rotate relative to the first support 310 in the second direction opposite to the first direction. Therefore, in a case that a parameter such as a rotation angle between the first support 310 and the base 100 does not change, a rotation angle between the first swing arm 210 and the base 100 is relatively reduced, to reduce a size of a part of the first sliding block 201 extending out of the first sliding groove 111. That is, when the hinge mechanism disclosed in this embodiment of this application is in a folded state, an overlap between the first sliding block 201 and the first sliding groove 111 is still relatively large. This can improve fit stability between the first sliding block 201 and the first sliding groove 111, and further improve reliability of the hinge mechanism.

In addition, to improve an anti-torsion capability of the hinge mechanism, in this embodiment of this application, the third swing arm 401 includes the first arm body 410 and the second arm body 420 that are disposed at an interval in the rotational axial direction, to ensure that the third swing arm 401 with a relatively small overall size can have a relatively large span in the rotational axial direction. Correspondingly, the first arm body 410 and the second arm body 420 are both in rotating fit with the base 100, and are both in sliding fit with the first support 310 in a direction perpendicular to the rotational axial direction, to ensure that actions of the first arm body 410 and the second arm body 420 are consistent.

In addition, the third swing arm 401 and the fourth swing arm 402 can form a transmission fit relationship through the first synchronous fitting member 501 and the second synchronous fitting member 502 that are in linkage connection, so that the third swing arm 401 and the fourth swing arm 402 can synchronously generate rotation actions in opposite directions relative to the base 100. In this way, the hinge mechanism has a synchronous rotation capability.

In addition, the third swing arm 401 is provided with the elastic member 610 and the cam member 620, so that the third swing arm 401 has a capability of hovering relative to the base 100, thereby extending an application scenario of the electronic device that uses the hinge mechanism. The elastic member 610 abuts against a side of the second arm body 420 of the third swing arm 401 away from the first arm body 410 through the cam member 620, so that the elastic member 610 can always squeeze the second arm body 420 through the cam member 620 in a manner in which the elastic member 610 has a preset elastic force. In this way, the second arm body 420 and the base 100 basically do not generate relative motion in the rotational axial direction, thereby improving action stability of the second arm body 420, and further improving structural accuracy and reliability of the entire hinge mechanism.

As described above, the first support 310 and the first swing arm 210 may be connected to each other through the second sliding groove 301 and the second sliding block 202 that are in sliding fit. A rotational connection structure between the second support 320 and the second swing arm 220 may still be a conventional shaft-hole connection structure. This can ensure that a rotating fit relationship can be formed between the second support 320 and the second swing arm 220.

To ensure relatively high reliability between the second support 320 and the second swing arm 220, in another embodiment of this application, one of the second swing arm 220 and the second support 320 may be provided with a second sliding block 202, the other is provided with a second sliding groove 301, the second sliding groove 301 has a component extending in a thickness direction of the second support 320, and the second sliding block 202 is slidably mounted in the second sliding groove 301. In a case that the second support 320 and the second swing arm 220 use the foregoing structure, when the second support 320 rotates in the second direction relative to the base 100, the second swing arm 220 may also rotate in the second direction relative to the base 100 along with the second support 320, and an end of the second swing arm 220 connected to the second support 320 can move relative to the second support 320 via a relative sliding relationship between the second sliding block 202 and the second sliding groove 301, so that the entire second swing arm 220 can rotate in the first direction relative to the second support 320. In this way, a rotation angle of the second swing arm 220 relative to the base 100 is reduced while a rotation angle of the first support 310 relative to the base 100 remains unchanged, so that an overlap between the first sliding block 201 of the second swing arm 220 and the corresponding first sliding groove 111 is still relatively large, thereby improving connection stability between the second swing arm 220 and the base 100, and further improving reliability of the hinge mechanism.

As described above, the second sliding groove 301 may be disposed on the first support 310, or may be disposed on the first swing arm 210. To reduce processing difficulty of each component, in this embodiment of this application, the second sliding groove 301 may be disposed on the first support 310. Correspondingly, the first swing arm 210 includes the second sliding block 202. For an extension direction of the second sliding groove 301, as described above, the second sliding groove 301 has a component in the thickness direction of the first support 310. Based on this, in some embodiments, the extension direction of the second sliding groove 301 is parallel to the thickness direction of the first support 310. In this case, when the hinge mechanism is in a folded state, a rotation angle of the first support 310 relative to the base 100 is 90°. In this case, the extension direction of the second sliding groove 301 is parallel to a thickness direction of the electronic device in a folded state, in other words, the extension direction of the second sliding groove 301 is perpendicular to both the thickness direction of the base 100 and the rotational axial direction of the hinge mechanism.

In another embodiment of this application, the extension direction of the second sliding groove 301 may be inclined relative to the thickness direction of the first support 310. Correspondingly, in a case that the rotation angle of the first support 310 relative to the base 100 is 90°, when the hinge mechanism is in a folded state, the extension direction of the second sliding groove 301 is also inclined relative to the thickness direction of the electronic device in the folded state. In other words, there is an included angle α between the extension direction of the second sliding groove 301 and the thickness direction of the first support 310, and 0°<α<90°.

Further, in a case that the hinge mechanism is in a folded state, the first support 310 and the second support 320 are disposed opposite to each other, and space formed between the first support 310 and the second support 320 is screen accommodating space. For the second sliding groove 301 disposed inclined relative to the thickness direction of the first support 310, a specific inclination direction of the second sliding groove 301 may be in a form of high inside and low outside. In detail, in a case that the hinge mechanism is in a folded state, a spacing between the base 100 and an end of the second sliding groove 301 disposed on the first support 310 close to the second support 320 is greater than a spacing between the base 100 and an end of the second sliding groove 301 away from the second support 320.

In a case that the foregoing technical solution is used, when the electronic device that uses the hinge mechanism accidentally falls in a folded state, and a side on which the base 100 in the hinge mechanism is located touches and collides with the ground, an interaction force between the first support 310 and the first swing arm 210 in the thickness direction of the base 100 can be decomposed into two component forces whose directions are perpendicular to each other. A magnitude of a component force in the thickness direction of the base 100 is necessarily less than a magnitude of a total acting force, so that a degree of interaction between the first support 310 and the first swing arm 210 is weaker, and a probability of damage of the first support 310 and the first swing arm 210 and another associated component can be reduced. A direction of the other component force is perpendicular to both the thickness direction of the base 100 and the rotational axial direction of the hinge mechanism, and the direction of the component force further points from an outer side of the first support 310 to an inner side of the first support 310. In this way, the component force has a function of enhancing a compact degree of a fit relationship between the first support 310 and the first swing arm 210. Therefore, it can be avoided that in a process in which the electronic device falls, an effect generated when a collision force acts on the electronic device causes components in the electronic device to be looser.

Similarly, in a case that the second sliding groove 301 is also disposed on the second support 320, a structure of the second sliding groove 301 on the second support 320 may be correspondingly designed with reference to a structure of the second sliding groove 301 on the first support 310. Intuitively, the second sliding groove 301 on the first support 310 and the second sliding groove 301 on the second support 320 may be disposed in a surface-symmetrical manner. That is, in a case that the hinge mechanism is in a folded state, a spacing between the base 100 and an end of the second sliding groove 301 disposed on the second support 320 close to the first support 310 is greater than a spacing between the base 100 and an end of the second sliding groove 301 away from the first support 310.

As described above, the hinge mechanism disclosed in this embodiment of this application includes the third swing arm 401 and the fourth swing arm 402, which are configured to provide a synchronization function, so that the first housing and the second housing in the electronic device can synchronously rotate toward each other or synchronously rotate away from each other. In addition, the third swing arm 401 and the fourth swing arm 402 form the foregoing synchronization relationship through the first synchronous fitting member 501 and the second synchronous fitting member 502. Specifically, both the first synchronous fitting member 501 and the second synchronous fitting member 502 may be gear-type structural members. That is, the third swing arm 401 and the fourth swing arm 402 may form a synchronous rotation relationship through a gear or gear group structure, so that the third swing arm 401 and the fourth swing arm 402 can synchronously rotate toward each other or synchronously rotate away from each other. To further reduce an overall thickness dimension of the hinge mechanism, in another embodiment of this application, the first synchronous fitting member 501 and the second synchronous fitting member 502 each are provided with a driving surface that is inclined relative to the rotational axial direction, and a corresponding inclined surface is also disposed for each of the third swing arm 401 and the fourth swing arm 402, so that the third swing arm 401 and the fourth swing arm 402 can also form a synchronous rotation relationship.

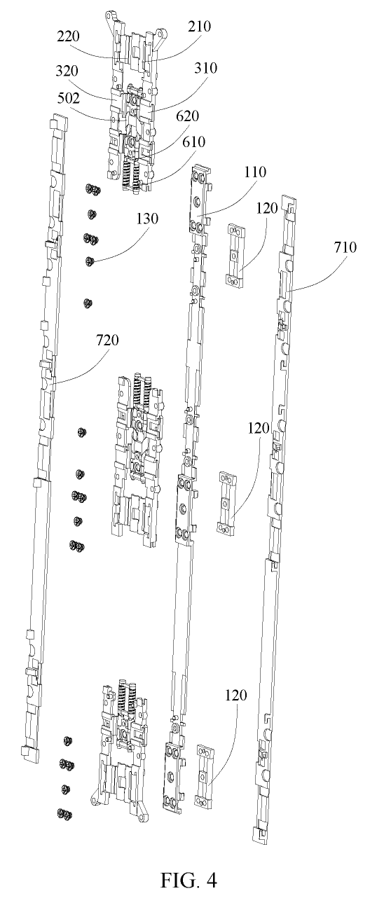

In detail, with reference to FIG. 1, FIG. 4, and FIG. 6, the first synchronous fitting member 501 and the second synchronous fitting member 502 are relatively fastened in the rotational axial direction of the hinge mechanism, and are both slidably connected to the base 100. Therefore, when the first synchronous fitting member 501 and the second synchronous fitting member 502 move relative to the base 100 in the rotational axial direction of the hinge mechanism, movement distances and movement directions of the first synchronous fitting member 501 and the second synchronous fitting member 502 are correspondingly the same. In some embodiments, the first synchronous fitting member 501 and the second synchronous fitting member 502 may be formed in an integrated molding manner, so that the first synchronous fitting member 501 and the second synchronous fitting member 502 are integrated, and then the first synchronous fitting member 501 and the second synchronous fitting member 502 can form a relative fastening relationship in the axial direction of the hinge mechanism. In some embodiments, the first synchronous fitting member 501 and the second synchronous fitting member 502 may be formed separately, and a fastening function is provided for the first synchronous fitting member 501 and the second synchronous fitting member 502 in the axial direction of the hinge mechanism through a structure such as a connector.

In addition, as shown in FIG. 6, the first synchronous fitting member 501 has a first inclined surface 510, the second synchronous fitting member 502 has a second inclined surface 520, the third swing arm 401 has a third inclined surface 411a, the fourth swing arm 402 has a fourth inclined surface 421a, the third inclined surface 411a is opposite to and fits with the first inclined surface 510 in the rotational axial direction, and the fourth inclined surface 421a is opposite to and fits with the second inclined surface 520 in the rotational axial direction. That is, the third swing arm 401 corresponds to and fits with the first synchronous fitting member 501, and the fourth swing arm 402 corresponds to and fits with the second synchronous fitting member 502.

In some embodiments, the first inclined surface 510, the second inclined surface 520, the third inclined surface 411a, and the fourth inclined surface 421a are all surfaces inclined relative to the axial direction of the hinge mechanism. Two of the four inclined surfaces that are disposed opposite to each other have a mutual fit capability. When one of the two inclined surfaces that fit with each other rotates relative to the base 100, a fit relationship between the two inclined surfaces that are in contact with each other can be used to convert rotational movement of the one of the two inclined surfaces into axial movement of the other. That is, in a process in which one of two components (for example, the third swing arm 401 and the first synchronous fitting member 501, or the fourth swing arm 402 and the second synchronous fitting member 502) that fit with each other generates relative rotation relative to the base 100 in a direction around the axial direction of the hinge mechanism, a fit relationship between included surfaces of the two components that fit with each other may be used to make the other generate straight-line movement relative to the base 100 in the axial direction of the hinge mechanism. Vice versa, that is, in a process in which one of two components generates straight-line movement relative to the base 100, the other may generate rotational movement relative to the base 100.

Correspondingly, based on different specific parameters of the surfaces that fit with each other and different parameters such as rotation directions of the third swing arm 401 and the fourth swing arm 402 relative to the base 100, in a process in which two components that fit with each other rotate relative to each other in a direction around the axial direction, the two components that fit with each other generate an action of moving close to each other or moving away from each other in the axial direction.

In addition, to ensure that the third swing arm 401 and the fourth swing arm 402 have a capability of synchronously rotating relative to the base 100, in this embodiment of this application, the first inclined surface 510 and the second inclined surface 520 are disposed opposite to each other in the axial direction of the hinge mechanism. In other words, in an example in which a first end of the first synchronous fitting member 501 and a first end of the second synchronous fitting member 502 are located on a same side, the first inclined surface 510 may be disposed on the first end of the first synchronous fitting member 501, and the second inclined surface 520 may be disposed on a second end of the second synchronous fitting member 502. That is, in the axial direction of the hinge mechanism, orientations of the first inclined surface 510 and the second inclined surface 520 are opposite, so that the third inclined surface 411a can be disposed on a side of the first inclined surface 510 away from the first synchronous fitting member 501, and the fourth inclined surface 421a is disposed on a side of the second inclined surface 520 away from the second synchronous fitting member 502.

In a case that the foregoing technical solution is used, in an example in which the third swing arm 401 is used as an active driver, the third swing arm 401 can push, via the third inclined surface 411a of the third swing arm 401, the first inclined surface 510 to move in the axial direction relative to the base 100. In an example in which the two inclined surfaces move away from each other, the third swing arm 401 can drive the first synchronous fitting member 501 to move in the axial direction away from the third inclined surface 411a. In this case, the first synchronous fitting member 501 can drive the second synchronous fitting member 502 to move away from the third inclined surface 411a together, so that the second synchronous fitting member 502 can apply an axial driving force to the fourth swing arm 402. Under the action of a fit relationship between the second inclined surface 520 and the fourth inclined surface 421a, the fourth swing arm 402 can passively rotate relative to the base 100 in a direction opposite to the rotation direction of the third swing arm 401, to provide avoidance space for axial movement of the second synchronous fitting member 502.

In general, in a case that the third swing arm 401 rotates relative to the base 100 as an active driver, the third inclined surface 411a can push the first inclined surface 510, so that the third swing arm 401 can transfer a rotation action of the third swing arm 401 to the first synchronous fitting member 501, and drive the first synchronous fitting member 501 and the second synchronous fitting member 502 to move in the axial direction of the hinge mechanism toward a first end of the base 100. In addition, a straight-line movement force of the second synchronous fitting member 502 may act on the fourth swing arm 402, so that the fourth inclined surface 421a is pushed via the second inclined surface 520, to drive the fourth swing arm 402 to rotate relative to the base 100. In this way, the fourth swing arm 402 and the third swing arm 401 have a capability of synchronously rotating relative to the base 100.

On the contrary, in a case that the fourth swing arm 402 rotates relative to the base 100 as an active driver, the fourth inclined surface 421a can push the second inclined surface 520, so that the fourth swing arm 402 can transfer a rotation action of the fourth swing arm 402 to the second synchronous fitting member 502, and drive the second synchronous fitting member 502 and the first synchronous fitting member 501 to move in the axial direction of the hinge mechanism toward a second end of the base 100. In addition, a straight-line movement force of the first synchronous fitting member 501 may act on the third swing arm 401, so that the third inclined surface 411a is pushed via the first inclined surface 510, to drive the third swing arm 401 to rotate relative to the base 100 in a direction opposite to the rotation direction of the fourth swing arm 402. In this way, the fourth swing arm 402 and the third swing arm 401 have a capability of synchronously rotating relative to the base 100.

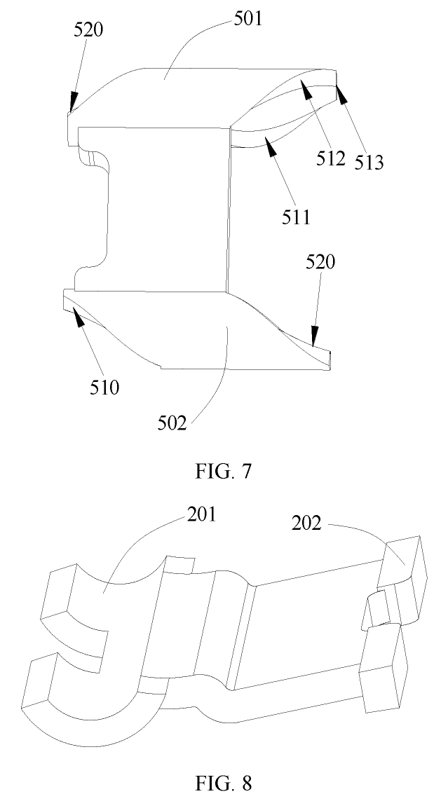

In the foregoing description, the foregoing technical objective may be implemented by designing an inclination direction of each of the third inclined surface 411a, the first inclined surface 510, the fourth inclined surface 421a, and the second inclined surface 520 in the hinge mechanism. In a specific embodiment of this application, as shown in FIG. 7, the first inclined surface 510 may include a first helical driving surface 511, a second helical driving surface 512, a first cut-off end face 513, and a second cut-off end face. In the direction around the rotational axial direction, the first helical driving surface 511, the first cut-off end face 513, the second helical driving surface 512, and the second cut-off end face are sequentially connected, and the second cut-off end face is connected to the first helical driving surface 511, so that the four surfaces are connected in a head-to-tail manner to form a closed-loop first inclined surface 510. In this way, the first inclined surface 510 includes two inclined surfaces used to provide a driving function, that is, the first helical driving surface 511, and the second helical driving surface 512, thereby improving a driving effect and a driven effect of the first inclined surface 510. In addition, the first cut-off end face 513 and the second cut-off end face are parallel to each other and are both perpendicular to the rotational axial direction, so that both the first cut-off end face 513 and the second cut-off end face have a function of mutual limiting with the third swing arm 401 in the rotational axial direction, thereby further improving a driving effect and a driven effect of the first synchronous fitting member 501.

In a case that the first inclined surface 510 uses the technical solution disclosed in the foregoing embodiment, a structure of the third inclined surface 411a of the third swing arm 401 that fits with the first inclined surface 510 may be correspondingly designed with reference to the structure of the first inclined surface 510, so that interaction between the third inclined surface 411a and the first inclined surface 510 is better. Similarly, both the second inclined surface 520 and the fourth inclined surface 421a may be designed with reference to the structure of the first inclined surface 510, so that synchronization performance between the third swing arm 401 and the fourth swing arm 402 is better.

For the foregoing technical solution in which the first synchronous fitting member 501 includes the first inclined surface 510, and the second synchronous fitting member 502 includes the second inclined surface 520, another explanation is further provided herein as follows.

In a case that the hinge mechanism is in an unfolded state, in the rotational axial direction of the hinge mechanism, a spacing between the first synchronous fitting member 501 and an end of the third swing arm 401 away from the third inclined surface 411a is a first spacing, and a spacing between the second synchronous fitting member 502 and an end of the fourth swing arm 402 away from the fourth inclined surface 421a is a second spacing. In a case that the hinge mechanism is in a folded state, in the axial direction, a spacing between the first synchronous fitting member 501 and the end of the third swing arm 401 away from the third inclined surface 411a is a third spacing, and a spacing between the second synchronous fitting member 502 and the end of the fourth swing arm 402 away from the fourth inclined surface 421a is a fourth spacing. The third spacing is less than the first spacing, and the fourth spacing is greater than the second spacing.

That is, in a process in which the hinge mechanism switches from the unfolded state to the folded state, the fourth swing arm 402 may be used as an active driver, and may rotate relative to the base 100 to drive the second synchronous fitting member 502 and the first synchronous fitting member 501 to move in the axial direction relative to the base 100 and away from the fourth swing arm 402, so that a spacing between the second synchronous fitting member 502 and the end of the fourth swing arm 402 away from the fourth inclined surface 421a increases from the second spacing to the fourth spacing, and a spacing between the first synchronous fitting member 501 and the end of the third swing arm 401 away from the third inclined surface 411a decreases from the first spacing to the third spacing. Correspondingly, under the action of straight-line movement of the first synchronous fitting member 501, to avoid the first synchronous fitting member 501, the third swing arm 401 rotates relative to the base 100, so that the third swing arm 401 and the fourth swing arm 402 rotate synchronously relative to the base 100.

Correspondingly, in a process in which the hinge mechanism switches from the folded state to the unfolded state, the third swing arm 401 may be used as an active driver, and a rotation action of the third swing arm 401 acts on the first synchronous fitting member 501 for switching to a straight-line movement action of the first synchronous fitting member 501 and the second synchronous fitting member 502, and then acts on the fourth swing arm 402, so that the fourth swing arm 402 rotates relative to the base 100.

In the hinge mechanism disclosed in the foregoing embodiment, the third swing arm 401 and the fourth swing arm 402 are respectively rotatably connected to two opposite sides of the base 100 of the hinge mechanism, and the first synchronous fitting member 501 and the second synchronous fitting member 502 that are relatively fastened in the axial direction of the hinge mechanism are further slidably mounted on the base 100. The third inclined surface 411a, the fourth inclined surface 421a, the first inclined surface 510, and the second inclined surface 520 are respectively disposed on the third swing arm 401, the fourth swing arm 402, the first synchronous fitting member 501, and the second synchronous fitting member 502, the third inclined surface 411a is opposite to and fits with the first inclined surface 510, and the fourth inclined surface 421a is opposite to and fits with the second inclined surface 520. In this way, between the third swing arm 401 and the first synchronous fitting member 501, and between the fourth swing arm 402 and the second synchronous fitting member 502, there is a capability of switching between straight-line movement relative to the base 100 and rotational movement relative to the base 100, so that the third swing arm 401 and the fourth swing arm 402 have a function of synchronously rotating relative to the base 100. In addition, the first inclined surface 510 and the second inclined surface 520 are disposed opposite to each other in the axial direction of the hinge mechanism, so that an acting force in the axial direction of the hinge mechanism can be sequentially transferred between the third swing arm 401, the first synchronous fitting member 501 (and the second synchronous fitting member 502), and the fourth swing arm 402, thereby ensuring that the third swing arm 401 and the fourth swing arm 402 have a capability of synchronously rotating relative to the base 100.

In addition, in the hinge mechanism disclosed in this embodiment of this application, because the first synchronous fitting member 501 and the second synchronous fitting member 502 are not gear-type structural members, in a process of designing the first synchronous fitting member 501 and the second synchronous fitting member 502, thicknesses of the first synchronous fitting member 501 and the second synchronous fitting member 502 (that is, dimensions of the first synchronous fitting member 501 and the second synchronous fitting member 502 in the thickness direction of the base 100, or dimensions in the thickness direction of the electronic device in an unfolded state) may be reduced to some extent, so that a thickness of the entire hinge mechanism may be relatively small, which facilitates lightening and thinning development of the electronic device using the hinge mechanism.

Based on the hinge mechanism of the foregoing structure disclosed in this embodiment of this application, further, in a case that the hinge mechanism is in one of an unfolded state and a folded state, the second inclined surface 520 is attached to the fourth inclined surface 421a. Correspondingly, in a case that the hinge mechanism is in the other one of the unfolded state and the folded state, the first inclined surface 510 is attached to the third inclined surface 411a.

For example, when the hinge mechanism is in the unfolded state, a spacing between the fourth swing arm 402 and the second synchronous fitting member 502 may be in a minimum state. Correspondingly, when the hinge mechanism is in the folded state, a spacing between the third swing arm 401 and the first synchronous fitting member 501 may be in a minimum state. In a case that the foregoing technical solution is used, when the hinge mechanism is in a critical state, an interaction effect between two of the third swing arm 401, the fourth swing arm 402, the first synchronous fitting member 501, and the second synchronous fitting member 502 that are corresponding to each other may be weakened, thereby improving a service life of each component. In addition, a dimension of the entire hinge mechanism in the axial direction of the hinge mechanism may be relatively small.

In addition, in the hinge mechanism, because the first inclined surface 510 and the second inclined surface 520 are disposed opposite to each other in the axial direction, to make the dimension of the entire hinge mechanism in the axial direction of the hinge mechanism relatively smaller, lengths of the first synchronous fitting member 501 and the second synchronous fitting member 502 may be substantially equal, and the first synchronous fitting member 501 and the second synchronous fitting member 502 are distributed in a direction perpendicular to the axial direction of the hinge mechanism. That is, the first synchronous fitting member 501 and the second synchronous fitting member 502 may be arranged in a substantially flush manner in the axial direction of the hinge mechanism. In this case, a sum of dimensions occupied by the first synchronous fitting member 501 and the second synchronous fitting member 502 in the axial direction of the hinge mechanism is relatively small, so that the dimension of the hinge mechanism in the axial direction of the hinge mechanism may be reduced.

To further improve ease of use of the hinge mechanism and the corresponding electronic device, as described above, the hinge mechanism disclosed in this embodiment of this application further includes a damping component, to enable the hinge mechanism and the electronic device to have a hover capability via the damping component, that is, to enable the electronic device to hover in another state between an unfolded state and a folded state, thereby improving ease of use of the device, and improving user experience.

In a case that the third swing arm 401 includes the first arm body 410 and the second arm body 420, the third inclined surface 411a may be disposed on the first arm body 410, and a cam surface is disposed at an end of the second arm body 420 away from the first arm body 410, so that the end of the second arm body 420 away from the first arm body 410 is in cam fit with the cam member 620.

To further improve stability of a synchronous transmission relationship between the third swing arm 401 and the fourth swing arm 402, based on the foregoing embodiment, the third swing arm 401 may further have the fourth inclined surface 421a, the fourth swing arm 402 may further have the third inclined surface 411a, the first synchronous fitting member 501 may further have the second inclined surface 520, and the second synchronous fitting member 502 may further have the second inclined surface 520. In this case, regardless of whether the hinge mechanism switches from the unfolded state to the folded state, or the hinge mechanism switches from the folded state to the unfolded state, the third swing arm 401 and the fourth swing arm 402 can be separately used as an active driver, thereby reducing use difficulty and vulnerability of the hinge mechanism, and improving user experience.

In more detail, in a case that the first synchronous fitting member 501 has the first inclined surface 510 and the second inclined surface 520, the third swing arm 401 corresponding to the first synchronous fitting member 501 has the third inclined surface 411a and the fourth inclined surface 421a, and in the axial direction, the first synchronous fitting member 501 may be disposed between the third inclined surface 411a and the fourth inclined surface 421a of the third swing arm 401, the third inclined surface 411a of the third swing arm 401 is opposite to and fits with the first inclined surface 510 of the first synchronous fitting member 501, and the fourth inclined surface 421a of the third swing arm 401 is opposite to and fits with the second inclined surface 520 of the first synchronous fitting member 501. Similarly, the second synchronous fitting member 502 may be disposed between the third inclined surface 411a and the fourth inclined surface 421a of the fourth swing arm 402, so that respective inclined surfaces of the second synchronous fitting member 502 and the fourth swing arm 402 are correspondingly disposed opposite to each other and fit with each other.

In addition, as described above, sizes of the first synchronous fitting member 501 and the second synchronous fitting member 502 may be made comparable, and the first synchronous fitting member 501 and the second synchronous fitting member 502 are disposed in a substantially flush manner in the axial direction, to reduce the dimension of the entire hinge mechanism in the axial direction. Based on this, in a process of arranging the third swing arm 401 and the fourth swing arm 402, the third swing arm 401 and the fourth swing arm 402 can be disposed in a flush manner in a direction perpendicular to the axial direction, so that the third swing arm 401 and the fourth swing arm 402 are disposed in a substantially flush manner in the axial direction, and the axial dimension of the hinge mechanism is relatively small.

As described above, the third inclined surfaces 411a and the fourth inclined surfaces 421a of the third swing arm 401 and the fourth swing arm 402 are disposed at an interval in the axial direction. Therefore, in a case that the third swing arm 401 includes the first arm body 410 and the second arm body 420, the fourth inclined surface 421a may be disposed on the second arm body 420 of the third swing arm 401. Similarly, like the third swing arm 401, the fourth swing arm 402 may also include the first arm body 410 and the second arm body 420 that are disposed at an interval in the rotational axial direction, the third inclined surface 411a is disposed on the first arm body 410 of the fourth swing arm 402, and the fourth inclined surface 421a is disposed on the second arm body 420 of the fourth swing arm 402. In addition, as described above, the first inclined surface 510 on the first synchronous fitting member 501 and the second inclined surface 520 on the second synchronous fitting member 502 are disposed opposite to each other in the rotational axial direction. Therefore, a direction of distribution of the first arm body 410 and the second arm body 420 of the fourth swing arm 402 may be opposite to a direction of distribution of the first arm body 410 and the second arm body 420 of the third swing arm 401.

Correspondingly, to ensure that the first synchronous fitting member 501 can still be disposed between the third inclined surface 411a and the fourth inclined surface 421a of the third swing arm 401, in the rotational axial direction, the first rotating portion 411 and the second rotating portion 421 are fixedly disposed at an interval, and the first connecting portion 412 and the second connecting portion 422 are fixedly disposed at an interval. In a case that the third swing arm 401 includes the first arm body 410 and the second arm body 420, because the first connecting portion 412 and the second connecting portion 422 are spaced apart from each other, a part of the third swing arm 401 used to connect to the first support 310 crosses a relatively large dimension in the axial direction, thereby improving fit stability between the entire third swing arm 401 and the first support 310. In addition, because the first connecting portion 412 and the second connecting portion 422 are spaced apart from each other in the axial direction, the third swing arm 401 may fit with the first support 310 through a dual-sliding fit structure. This may further improve fitting accuracy of the third swing arm 401 and the first support 310, and may improve smoothness of an action between the third swing arm 401 and the first synchronous fitting member 501.

In addition, a structure such as a connection beam may be disposed between the first connecting portion 412 and the second connecting portion 422, so that the first arm body 410 and the second arm body 420 can form a relative fastening relationship in the axial direction. In some embodiments, a fastening support 650 mentioned below may be disposed between the first arm body 410 and the second arm body 420 of the third swing arm 401, and the fastening support 650 provides a limiting function for the first arm body 410 and the second arm body 420 in the rotational axial direction. Similarly, in a case that the fourth swing arm 402 also includes the first arm body 410 and the second arm body 420, the fastening support 650 may also be correspondingly disposed, so that the first arm body 410 and the second arm body 420 of the fourth swing arm 402 provide a limiting function in the rotational axial direction.

As described above, both the first arm body 410 and the second arm body 420 of the third swing arm 401 are in sliding fit with the first support 310. Therefore, as shown in FIG. 6, two axial limiting structures may be disposed on the first support 310, the two axial limiting structures each have a sliding groove, and the first connecting portion 412 and the second connecting portion 422 of the third swing arm 401 may respectively extend into respective sliding grooves of the two axial limiting structures, so that both the first connecting portion 412 and the second connecting portion 422 can form a sliding fit relationship with the first support 310 in a direction perpendicular to the axial direction. In addition, the two axial limiting structures may further limit a relative position relationship between the first connecting portion 412 and the second connecting portion 422 and the first support 310 in the axial direction, to prevent the first connecting portion 412 and the second connecting portion 422 from moving relative to the first support 310 in the axial direction.

In a case that the foregoing technical solution is used to limit the axial position relationship between the third swing arm 401 and the first support 310, the first arm body 410 and the second arm body 420 do not need to be fastened in advance, thereby further reducing difficulty of processing and assembling the hinge mechanism. In addition, a dimension of the axial limiting structure in an extension direction of the first connecting portion 412 may be increased to some extent, and a dimension of limiting fit between the axial limiting structure and the first arm body 410 (and the second arm body 420) in the direction perpendicular to the axial direction may be further increased, to further improve a limiting effect of the axial limiting structure.

As described above, the foregoing embodiment describes a structure and an assembly relationship of the third swing arm 401. Similarly, the fourth swing arm 402 may be correspondingly designed with reference to the structure of the third swing arm 401 described in the foregoing embodiment, so that fit stability between the fourth swing arm 402 and the second support 320 and between the fourth swing arm 402 and the base 100 is relatively high, thereby improving overall performance of the hinge mechanism.

As described above, the cam member 620 may be disposed on the side of the third swing arm 401 away from the third inclined surface 411a of the third swing arm 401. Based on this, in a case that both the third swing arm 401 and the fourth swing arm 402 have the third inclined surface 411a and the fourth inclined surface 421a, as shown in FIG. 6, a cam surface and the cam member 620 may be disposed on a side of the fourth swing arm 402 away from the third inclined surface 411a of the fourth swing arm 402, that is, two cam members 620 are respectively located on sides of two third inclined surfaces 421a away from corresponding fourth inclined surfaces 411a.

In addition, the two cam members 620 that respectively fit with the third swing arm 401 and the fourth swing arm 402 are relatively fastened in the axial direction, so that both the two cam members 620 may be in elastic fit with the same elastic member 610. Therefore, in a process in which the hinge mechanism switches between the unfolded state and the folded state, regardless of whether the third swing arm 401 or the fourth swing arm 402 is used as an active driver, in a process of being driven to rotate relative to the base 100, the corresponding cam member 620 is directly driven to move in the axial direction, and squeeze the elastic member 610. This may reduce difficulty in driving the cam member 620, greatly reduce a probability of jamming of a driven member in the cam member 620, the elastic member 610, the third swing arm 401, and the fourth swing arm 402, and improve reliability and smoothness of the hinge mechanism.

In a case that the cam member 620 is disposed on a side of each of the third swing arm 401 and the fourth swing arm 402 away from the third inclined surface 411a, to further improve reliability of the hinge mechanism, the elastic member 610 may be disposed on a side of each cam member 620 away from the first synchronous fitting member 501. In this way, regardless of whether the third swing arm 401 is used as an active driver or the fourth swing arm 402 is used as an active driver, the cam member 620 may drive the elastic member 610 that is distributed in the axial direction with the cam member 620 to be squeezed, so that an acting force is transferred linearly, thereby further preventing a jamming phenomenon in a working process of the hinge mechanism.

In some embodiments, two cam members 620 that are respectively located on a same side of the third swing arm 401 and the fourth swing arm 402 are formed in an integrated molding manner, to ensure that the two cam members 620 have a relative fastening capability in the axial direction, and reduce difficulty in processing and assembling the hinge mechanism. After the two cam members 620 are separately molded, the two cam members 620 can form a relative fastening relationship in the axial direction in a manner of bonding or the like.

As described above, in a process of using the hinge mechanism, the third swing arm 401 and the fourth swing arm 402 may be directly or indirectly connected to the first housing and the second housing of the electronic device respectively. Based on this, neither of the third swing arm 401 and the fourth swing arm 402 can move relative to the base 100 in the axial direction. Therefore, in a process in which the third swing arm 401 and the fourth swing arm 402 rotate relative to the base 100, cam members 620 that respectively fit with the third swing arm 401 and the fourth swing arm 402 move relative to the base 100 in the axial direction, that is, the cam member 620 has a capability of moving relative to the base 100 in the axial direction. Further, to improve fit stability between the cam member 620 and the base 100, a mounting structure such as a limiting groove may be disposed on the base 100 for the cam member 620.

In another embodiment of this application, as shown in FIG. 6, the hinge mechanism may further include a synchronous shaft 630, and the synchronous shaft 630 may be disposed for each of the third swing arm 401 and the fourth swing arm 402, so that the third swing arm 401 and the fourth swing arm 402 each can form a relatively reliable rotating fit relationship with the base 100 through the corresponding synchronous shaft 630. Based on this, two cam members 620 located on sides of the third swing arm 401 and the fourth swing arm 402 away from respective third inclined surfaces 411a are respectively sleeved on two synchronous shafts 630, thereby improving fit reliability between the cam members 620 and the synchronous shafts 630.

In addition, in a case that the synchronous shaft 630 is disposed, as described above, the elastic member 610 may be a compression spring. Therefore, the elastic member 610 may be sleeved outside the synchronous shaft 630. In a case that the elastic member 610 is disposed on each of the third swing arm 401 and the fourth swing arm 402, the elastic member 610 may be sleeved outside each synchronous shaft 630, to ensure relatively high working stability of each elastic member 610.

As described above, the cam surface and the cam member 620 may be disposed on a side of each of the third swing arm 401 and the fourth swing arm 402 away from the third inclined surface 411a, and the hinge mechanism is provided with a hover capability through the elastic member 610. To improve reliability of the hinge mechanism in a hovering state, in another embodiment of this application, the third swing arm 401 and the fourth swing arm 402 each are provided with cam members 620 on two opposite sides in the rotational axial direction, so that in a process in which the third swing arm 401 and the fourth swing arm 402 rotate relative to the base 100, the cam members 620 located on the two opposite sides may be driven together to move away from each other. This may further increase a damping force of the hinge mechanism, thereby improving stability when the hinge mechanism is in the hovering state.

In the foregoing embodiment, the elastic member 610 may be disposed at an end of the second arm body 420 in the third swing arm 401 away from the first arm body 410. Based on this, to ensure that a corresponding damping force can be provided when an end of the first arm body 410 in the third swing arm 401 away from the second arm body 420 fits with the corresponding cam member 620, in a specific embodiment of this application, one or more other elastic members 610 may be further disposed on a side of the first arm body 410 in the third swing arm 401 away from the second arm body 420.

To reduce a quantity of components disposed in the hinge mechanism and improve reliability of the hinge mechanism, in another embodiment of this application, as shown in FIG. 6 and with reference to FIG. 4, one or more elastic members 610 distributed side by side in a direction perpendicular to the rotational axial direction may be disposed on only a side of the second arm body 420 in the third swing arm 401 away from the first arm body 410. In addition, each synchronous shaft 630 is in movable fit with the base 100 in the rotational axial direction, to ensure that the cam member 620 located on the side of the third swing arm 401 away from the third inclined surface 411a of the third swing arm 401 (that is, the side of the first arm body 410 away from the second arm body 420) can fit with the cam surface of the first arm body 410, and a damping effect is generated. This may further reduce the dimension of the hinge mechanism in the rotational axial direction.

This embodiment of this application further includes a snap ring 660, and a limiting groove is disposed on the synchronous shaft 630, so that the snap ring 660 is clamped in the limiting groove, and the snap ring 660 can form an axial limiting relationship with the synchronous shaft 630, to provide components such as the elastic member 610 and the cam member 620 with an axial limiting function. Further, in the axial direction of the hinge mechanism, the cam member 620 located on the side of the third swing arm 401 away from the third inclined surface 411a of the third swing arm 401 may form a relative fastening relationship with the synchronous shaft 630 through the snap ring 660, so that in a process in which the third swing arm 401 rotates relative to the base 100, the cam member 620 located on the side of the third swing arm 401 away from the third inclined surface 411a of the third swing arm 401 can be driven to move away from the third swing arm 401, and in a process in which the cam member 620 moves in the axial direction, an end at which the elastic member 610 is located in the synchronous shaft 630 that is fastened to the cam member 620 can be driven to move toward the third swing arm 401 relative to the base 100, so that the synchronous shaft 630 squeezes the elastic member 610.

In addition, in a process in which the third swing arm 401 rotates relative to the base 100, the third swing arm 401 may further drive the fourth swing arm 402 to rotate relative to the base 100 through the first synchronous fitting member 501 and the second synchronous fitting member 502. In a process in which the fourth swing arm 402 rotates, the cam member 620 disposed on the side of the fourth swing arm 402 away from the fourth inclined surface 421a of the fourth swing arm 402 may also be driven by the fourth swing arm 402, and move away from the fourth swing arm 402 in the axial direction. In a process in which the cam member 620 moves, the elastic member 610 may be further squeezed, so that two opposite ends of the elastic member 610 further move close to each other, and an elastic force of the elastic member 610 is increased. In this way, a damping effect of the hinge mechanism is improved, hovering stability of the hinge mechanism is improved, and the axial dimension of the entire hinge mechanism is relatively small.

In addition, in this embodiment of this application, because each synchronous shaft 630 has a capability of moving in the axial direction relative to the base 100, shaft sleeves 651 distributed at an interval in the axial direction may be disposed on the base 100, and each synchronous shaft 630 is disposed between at least two shaft sleeves 651, to provide the synchronous shaft 630 with limiting and guiding functions, thereby improving fit stability between the synchronous shaft 630 and the base 100.

In another embodiment of this application, as shown in FIG. 6, the hinge mechanism may further include a plurality of fastening supports 650 disposed at an interval in the rotational axial direction. The fastening support 650 may be fixedly mounted on the base 100 through a removable connector such as a screw, and adjacent fastening supports 650 are spaced apart from each other in the axial direction. The fastening support 650 may be provided with the foregoing shaft sleeve 651, so that fit stability between each synchronous shaft 630 and the base 100 is relatively high. In addition, in a case that this embodiment of this application is used, the base 100 is further provided with a precondition of forming in an integrated molding manner, to avoid that the base 100 cannot be normally demolded because the shaft sleeve 651 that is not detachable from the base 100 needs to be disposed on the base 100.

In addition, in a case that the foregoing technical solution is used, the shaft sleeve 651 may further be used to provide a limiting function for the first arm body 410 and the second arm body 420 of the third swing arm 401. In detail, because both the synchronous shaft 630 and the third swing arm 401 form a rotating fit relationship with the base 100, the synchronous shaft 630 may pass through both the shaft sleeve 651 and the third swing arm 401, and an opening 401a is disposed on each of the first arm body 410 and the second arm body 420 of the third swing arm 401, so that the shaft sleeve 651 is separately accommodated via the opening, and the first arm body 410 and the second arm body 420 can form a limiting fit relationship with the corresponding shaft sleeve 651 in the rotational axial direction, thereby further improving assembly stability of the third swing arm 401 and the base 100 in the rotational axial direction. In a case that the fourth swing arm 402 also includes the first arm body 410 and the second arm body 420, the fastening support 650 and the shaft sleeve 651 may be correspondingly disposed in the fourth swing arm 402.

In the base 100 disclosed in another embodiment of this application, the base 100 may be formed in a separated molding manner. In some embodiments, the base 100 includes a base body 110 and a cover 120, the base body 110 is provided with an arc-shaped first sliding groove 111, and the cover 120 may form a detachably fixed connection relationship with the base body 110 through a threaded connector 130. This may reduce overall processing difficulty of the base 100. To support a component such as the display, an avoidance hole may also be disposed on the cover 120, so that an end of the first sliding block 201 away from the second sliding block 202 can extend out of the base 100 through the avoidance hole. In addition, to reduce an overall thickness of the base 100, in a process of forming a threaded hole on the base body 110, the threaded hole may occupy a part of space at a position of the first sliding groove 111, and a solid structure is formed. In this case, to avoid the solid structure, an avoidance opening may be disposed at an end portion of the first sliding block 201, to avoid the solid structure through the avoidance opening. Therefore, the first sliding block 201 can further form a limit relationship with the solid structure in the rotational axial direction of the hinge mechanism, thereby further improving fit reliability between the first swing arm 210 and the first support 310.

In the hinge mechanism disclosed in this embodiment of this application, only one first swing arm 210, one second swing arm 220, one third swing arm 401, and one fourth swing arm 402 may be included. Correspondingly, one first synchronous fitting member 501, one second synchronous fitting member 502, and the like are further included. In another embodiment of this application, one first swing arm 210, one second swing arm 220, one third swing arm 401, one fourth swing arm 402, one first synchronous fitting member 501, one second synchronous fitting member 502, and the like may form a hinge assembly, and the hinge mechanism includes a plurality of hinge assemblies that are distributed at an interval in the axial direction of the hinge mechanism. Under the action of the plurality of hinge assemblies, connection reliability and folding smoothness of the hinge mechanism and the first housing and the second housing of the electronic device can be improved, and torsional deformation of the flexible display 900 in a folding and unfolding process can be prevented. In some embodiments, the base 100 may include one base body 110, and includes a plurality of covers 120. The plurality of covers 120 are in one-to-one correspondence with the plurality of hinge assemblies.

In another embodiment of this application, a middle plate 730 may further be disposed between any two adjacent hinge assemblies. Similar to the first door plate 710 and the second door plate 720 mentioned in the foregoing embodiment, the middle plate 730 may also provide a support function for the flexible display 900, thereby further improving a supported effect of the flexible display 900. In addition, the middle plate 730 is connected to hinge assemblies on two adjacent sides of the middle plate 730 in a welded manner, to further improve connection reliability and stability of the plurality of hinge assemblies. It should be noted that a spacing between any two adjacent hinge assemblies may be the same or different, which is not limited in this specification.

Based on the hinge mechanism disclosed in any one of the foregoing embodiments of this application, an embodiment of this application further discloses an electronic device. The electronic device includes any one of the foregoing hinge mechanisms. The electronic device may further include components such as a flexible display 900, a first housing, a second housing, and a battery. The first housing and the second housing are connected through the hinge mechanism, and provide a support function for the flexible display 900 together. The battery is used to supply power to a power-consuming component in the electronic device. In addition, another electronic component such as a camera module may be further disposed in the electronic device. In consideration of brevity of this specification, details are not described one by one herein.

The foregoing describes the embodiments of this application with reference to the accompanying drawings. However, this application is not limited to the foregoing specific implementations. The foregoing specific implementations are merely illustrative rather than restrictive. Inspired by this application, a person of ordinary skill in the art may develop many other manners without departing from principles of this application and the protection scope of the claims, and all such manners fall within the protection scope of this application.

1. A hinge mechanism, comprising a base, a first swing arm, a first support, a third swing arm, a fourth swing arm, a first synchronous fitting member, a second synchronous fitting member, an elastic member, and a cam member, wherein:
the base is provided with an arc-shaped first sliding groove, a first end of the first swing arm is provided with an arc-shaped first sliding block, and the first sliding block is rotatably connected to the first sliding groove;
one of a second end of the first swing arm and the first support is provided with a second sliding block, the other is provided with a second sliding groove, and the second sliding block and the second sliding groove slide relative to each other in a thickness direction of the first support in a process in which the first support rotates relative to the base;
both the third swing arm and the first swing arm are disposed on a same side of the base, the third swing arm comprises a first arm body and a second arm body, and the first arm body and the second arm body are disposed at an interval in a rotational axial direction of the first swing arm;
both the first arm body and the second arm body are rotatably connected to the base, and both the first arm body and the second arm body are in sliding fit with the first support in a direction perpendicular to the rotational axial direction;
the first synchronous fitting member and the second synchronous fitting member are in linkage connection and both are movably mounted on the base, both the first arm body and the second arm body are in transmission fit with the first synchronous fitting member, the fourth swing arm is in transmission fit with the second synchronous fitting member, and the third swing arm and the fourth swing arm are reversely rotatable relative to the base; and
the cam member is slidably mounted on the base in the rotational axial direction, the cam member is relatively fastened to the base in a direction around the rotational axial direction, the cam member is disposed on an end face at an end of the second arm body away from the first arm body, the second arm body is in cam fit with the cam member, and in the rotational axial direction, one end of the elastic member abuts against a side of the cam member away from a cam surface of the cam member, and the other end of the elastic member is relatively fastened to the base.

2. The hinge mechanism according to claim 1, further comprising:
a second swing arm and a second support, the second swing arm and the first swing arm are disposed on two opposite sides of the base;
a plurality of first sliding grooves; and
a plurality of first sliding blocks rotatably connected to the plurality of first sliding grooves in one-to-one correspondence,
wherein a first end of the second swing arm is provided with an arc-shaped first sliding block,
one of a second end of the second swing arm and the second support is provided with a second sliding block, the other one of the second swing arm and the second support is provided with a second sliding groove, and
the second sliding block of the second swing arm and the second sliding groove of the second support slide relative to each other in a thickness direction of the second support in a process in which the second support rotates relative to the base.

3. The hinge mechanism according to claim 2, wherein:
the first support is provided with the second sliding groove, an included angle between an extension direction of the second sliding groove and the thickness direction of the first support is α, 0°<α<90°,
in a state in which the first support and the second support are opposite to each other, screen accommodating space is formed between the first support and the second support, and
a spacing between an end of the second sliding groove close to the second support and the base is greater than a spacing between an end of the second sliding groove away from the second support and the base.

4. The hinge mechanism according to claim 1, wherein:
the first synchronous fitting member and the second synchronous fitting member are relatively fastened in the rotational axial direction, and are slidably connected to the base;
the first synchronous fitting member has a first inclined surface, the second synchronous fitting member has a second inclined surface, the third swing arm has a third inclined surface, the fourth swing arm has a fourth inclined surface, the third inclined surface is opposite to and fits with the first inclined surface, and the fourth inclined surface is opposite to and fits with the second inclined surface;
when the third swing arm rotates relative to the base, the third inclined surface pushes the first inclined surface to drive the first synchronous fitting member and the second synchronous fitting member to move relative to the base in the rotational axial direction, and the second inclined surface pushes the fourth inclined surface to drive the fourth swing arm to rotate relative to the base in a direction opposite to a rotation direction of the third swing arm; and
when the fourth swing arm rotates relative to the base, the fourth inclined surface pushes the second inclined surface to drive the first synchronous fitting member and the second synchronous fitting member to move relative to the base in the rotational axial direction, and the first inclined surface pushes the third inclined surface to drive the third swing arm to rotate relative to the base in a direction opposite to a rotation direction of the fourth swing arm.

5. The hinge mechanism according to claim 4, wherein:
in the third swing arm, the first arm body is provided with the third inclined surface, the end of the second arm body away from the first arm body is in cam fit with the cam member, and the second arm body is further provided with the fourth inclined surface; and
the fourth swing arm is further provided with the third inclined surface, the first synchronous fitting member further has the second inclined surface, and the second synchronous fitting member further has the first inclined surface; and in the rotational axial direction, the first synchronous fitting member is disposed between the third inclined surface and the fourth inclined surface of the third swing arm, and the second synchronous fitting member is disposed between the third inclined surface and the fourth inclined surface of the fourth swing arm.

6. The hinge mechanism according to claim 5, wherein:
the cam surface and the cam member are disposed on a side of the fourth swing arm away from the third inclined surface of the fourth swing arm, and two cam members that respectively fit with the third swing arm and the fourth swing arm are relatively fastened in the axial direction; and
the third swing arm and the fourth swing arm each is rotatably mounted on the base through a synchronous shaft, the elastic member is sleeved outside each synchronous shaft, one end of each elastic member is relatively fastened to the synchronous shaft, and the other end of each elastic member abuts against two cam members.

7. The hinge mechanism according to claim 4, wherein:
the third swing arm is rotatably mounted on the base through a synchronous shaft, and the synchronous shaft and the base are in movable fit in the rotational axial direction and are in limiting fit in a direction perpendicular to the rotational axial direction; and
the cam member is disposed on each of two opposite sides of the third swing arm in the rotational axial direction, each cam member is relatively fastened to the synchronous shaft in the rotational axial direction, and an end of the first arm body away from the second arm body and the end of the second arm body away from the first arm body are in cam fit with two cam members in one-to-one correspondence.

8. The hinge mechanism according to claim 4, further comprising:
a fastening support fixedly mounted on the base,
wherein the fastening support is provided with a shaft sleeve, and the synchronous shaft passes through the shaft sleeve; and
the first arm body and the second arm body of the third swing arm each are provided with the shaft sleeve, and the first arm body and the second arm body each are in limiting fit with the shaft sleeve in the rotational axial direction.

9. The hinge mechanism according to claim 4, wherein:
the first inclined surface comprises a first helical driving surface, a second helical driving surface, a first cut-off end face, and a second cut-off end face;
in the direction around the rotational axial direction, the first helical driving surface, the first cut-off end face, the second helical driving surface, and the second cut-off end face are sequentially connected, and the second cut-off end face is connected to the first helical driving surface; and
the first cut-off end face and the second cut-off end face are parallel to each other and both are perpendicular to the rotational axial direction.

10. An electronic device, comprising:
a hinge mechanism, comprising a base, a first swing arm, a first support, a third swing arm, a fourth swing arm, a first synchronous fitting member, a second synchronous fitting member, an elastic member, and a cam member, wherein:
the base is provided with an arc-shaped first sliding groove, a first end of the first swing arm is provided with an arc-shaped first sliding block, and the first sliding block is rotatably connected to the first sliding groove;
one of a second end of the first swing arm and the first support is provided with a second sliding block, the other is provided with a second sliding groove, and the second sliding block and the second sliding groove slide relative to each other in a thickness direction of the first support in a process in which the first support rotates relative to the base;
both the third swing arm and the first swing arm are disposed on a same side of the base, the third swing arm comprises a first arm body and a second arm body, and the first arm body and the second arm body are disposed at an interval in a rotational axial direction of the first swing arm;
both the first arm body and the second arm body are rotatably connected to the base, and both the first arm body and the second arm body are in sliding fit with the first support in a direction perpendicular to the rotational axial direction;
the first synchronous fitting member and the second synchronous fitting member are in linkage connection and both are movably mounted on the base, both the first arm body and the second arm body are in transmission fit with the first synchronous fitting member, the fourth swing arm is in transmission fit with the second synchronous fitting member, and the third swing arm and the fourth swing arm are reversely rotatable relative to the base; and
the cam member is slidably mounted on the base in the rotational axial direction, the cam member is relatively fastened to the base in a direction around the rotational axial direction, the cam member is disposed on an end face at an end of the second arm body away from the first arm body, the second arm body is in cam fit with the cam member, and in the rotational axial direction, one end of the elastic member abuts against a side of the cam member away from a cam surface of the cam member, and the other end of the elastic member is relatively fastened to the base.

11. The electronic device according to claim 10, wherein the hinge mechanism further comprises:
a second swing arm and a second support, the second swing arm and the first swing arm are disposed on two opposite sides of the base;
a plurality of first sliding grooves; and
a plurality of first sliding blocks rotatably connected to the plurality of first sliding grooves in one-to-one correspondence,
wherein a first end of the second swing arm is provided with an arc-shaped first sliding block,
one of a second end of the second swing arm and the second support is provided with a second sliding block, the other one of the second swing arm and the second support is provided with a second sliding groove, and
the second sliding block of the second swing arm and the second sliding groove of the second support slide relative to each other in a thickness direction of the second support in a process in which the second support rotates relative to the base.

12. The electronic device according to claim 11, wherein:
the first support is provided with the second sliding groove, an included angle between an extension direction of the second sliding groove and the thickness direction of the first support is α, 0°<α<90°,
in a state in which the first support and the second support are opposite to each other, screen accommodating space is formed between the first support and the second support, and
a spacing between an end of the second sliding groove close to the second support and the base is greater than a spacing between an end of the second sliding groove away from the second support and the base.

13. The electronic device according to claim 10, wherein:
the first synchronous fitting member and the second synchronous fitting member are relatively fastened in the rotational axial direction, and are slidably connected to the base;
the first synchronous fitting member has a first inclined surface, the second synchronous fitting member has a second inclined surface, the third swing arm has a third inclined surface, the fourth swing arm has a fourth inclined surface, the third inclined surface is opposite to and fits with the first inclined surface, and the fourth inclined surface is opposite to and fits with the second inclined surface;
when the third swing arm rotates relative to the base, the third inclined surface pushes the first inclined surface to drive the first synchronous fitting member and the second synchronous fitting member to move relative to the base in the rotational axial direction, and the second inclined surface pushes the fourth inclined surface to drive the fourth swing arm to rotate relative to the base in a direction opposite to a rotation direction of the third swing arm; and
when the fourth swing arm rotates relative to the base, the fourth inclined surface pushes the second inclined surface to drive the first synchronous fitting member and the second synchronous fitting member to move relative to the base in the rotational axial direction, and the first inclined surface pushes the third inclined surface to drive the third swing arm to rotate relative to the base in a direction opposite to a rotation direction of the fourth swing arm.

14. The electronic device according to claim 13, wherein:
in the third swing arm, the first arm body is provided with the third inclined surface, the end of the second arm body away from the first arm body is in cam fit with the cam member, and the second arm body is further provided with the fourth inclined surface; and
the fourth swing arm is further provided with the third inclined surface, the first synchronous fitting member further has the second inclined surface, and the second synchronous fitting member further has the first inclined surface; and in the rotational axial direction, the first synchronous fitting member is disposed between the third inclined surface and the fourth inclined surface of the third swing arm, and the second synchronous fitting member is disposed between the third inclined surface and the fourth inclined surface of the fourth swing arm.

15. The electronic device according to claim 14, wherein:
the cam surface and the cam member are disposed on a side of the fourth swing arm away from the third inclined surface of the fourth swing arm, and two cam members that respectively fit with the third swing arm and the fourth swing arm are relatively fastened in the axial direction; and
the third swing arm and the fourth swing arm each is rotatably mounted on the base through a synchronous shaft, the elastic member is sleeved outside each synchronous shaft, one end of each elastic member is relatively fastened to the synchronous shaft, and the other end of each elastic member abuts against two cam members.

16. The electronic device according to claim 13, wherein:
the third swing arm is rotatably mounted on the base through a synchronous shaft, and the synchronous shaft and the base are in movable fit in the rotational axial direction and are in limiting fit in a direction perpendicular to the rotational axial direction; and
the cam member is disposed on each of two opposite sides of the third swing arm in the rotational axial direction, each cam member is relatively fastened to the synchronous shaft in the rotational axial direction, and an end of the first arm body away from the second arm body and the end of the second arm body away from the first arm body are in cam fit with two cam members in one-to-one correspondence.

17. The electronic device according to claim 13, wherein the hinge mechanism further comprises:
a fastening support fixedly mounted on the base,
wherein the fastening support is provided with a shaft sleeve, and the synchronous shaft passes through the shaft sleeve; and
the first arm body and the second arm body of the third swing arm each are provided with the shaft sleeve, and the first arm body and the second arm body each are in limiting fit with the shaft sleeve in the rotational axial direction.

18. The electronic device according to claim 13, wherein:
the first inclined surface comprises a first helical driving surface, a second helical driving surface, a first cut-off end face, and a second cut-off end face;
in the direction around the rotational axial direction, the first helical driving surface, the first cut-off end face, the second helical driving surface, and the second cut-off end face are sequentially connected, and the second cut-off end face is connected to the first helical driving surface; and
the first cut-off end face and the second cut-off end face are parallel to each other and both are perpendicular to the rotational axial direction.
